(19) United States
(12) Patent Application Publication
(10) Pub. No.: US 2026/0367116 A1
(43) Pub. Date: Nov. 19, 2026

(54) DOUBLE ISOLATION INPUT/OUTPUT CONNECTIONS

(71) Applicant: ITRON, INC., Liberty Lake, WA (US)

(72) Inventors: Stephen Ross SANNER, Seneca, SC (US); Brent Timothy MARTIN, Anderson, SC (US)

(21) Appl. No.: 19/209,038

(22) Filed: May 15, 2025

(51) Int. Cl. G01R 15/22; G01R 21/00

(52) U.S. Cl. CPC G01R 15/22; G01R 21/007

(57) ABSTRACT

Various embodiments disclose an isolation device that includes an isolation distance that is greater than or equal to a physical spacing threshold. The isolation device includes a first electrical isolator coupled to a second electrical isolator to provide the isolation distance between a first side of an area of electrical isolation of the isolation device and a second side of the area of electrical isolation, where the distance includes a combination of a first distance of the first electrical isolating component and a second distance of the second electrical isolating component.

### BACKGROUND

### Field of the Various Embodiments

The various embodiments relate generally to isolation devices, and more specifically, to double isolation techniques for isolating input/output connections for meters and other devices.

### Description of the Related Art

Enterprises can manage a large number of remote devices such as metering devices. For example, enterprises that control and/or monitor large infrastructure systems (e.g., power, water, traffic control, and the like) can include many thousands of devices (e.g., valves, metering devices, controllers, and the like). Some metering devices have high voltage connections, which are subject to certain safety standards. For example, the Underwriters Laboratories (UL)2735 safety standard is designed to reduce safety concerns for smart meters having accessible outputs. The UL2735 safety standard includes physical spacing requirements for accessible parts, such as cables exiting a meter protective cover. The physical spacing requirements include clearance and creepage distance requirements for the cables exiting a meter protective cover relative to other voltages (e.g., source voltages) within the meter. For example, the physical spacing requirements are applicable to an internal meter circuit from a KYZ output and load-side (or line-side) connections for KYZ pulses.

### BRIEF DESCRIPTION OF THE DRAWINGS

So that the manner in which the features of the various embodiments can be understood in detail, a description of the inventive concepts may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a diagram of an example of an electrical isolation system, according to various embodiments.

FIG. 2 is a diagram of another example of an electrical isolation system, according to various embodiments.

FIG. 3 is a diagram of another example of an electrical isolation system, according to various embodiments.

FIG. 4 is an electrical schematic diagram of an electrical isolation system, according to various embodiments.

FIG. 5 illustrates a flow diagram of method steps for providing electrical isolation, according to various embodiments.

### DETAILED DESCRIPTION

In the following description, numerous specific details are set forth to provide a more thorough understanding of the various embodiments. However, it will be apparent to one of skill in the art that the inventive concepts may be practiced without one or more of these specific details.

The techniques described involve electrical isolation devices that provide increased isolation using multiple isolation barriers connected or coupled in series. As a result, the combined isolation area, zone, or region created by the described electrical isolation devices have a total clearance and total creepage distance that exceed a physical spacing threshold (e.g., to satisfy a particular safety standard such as UL2735). In some examples, the sum of individual clearances and/or creepage distances of two or more isolation barriers provides one or more physical distance requirements that meet the safety standard.

At least one technical advantage of the disclosed techniques is that the disclosed techniques, one or more physical distance requirements are provided without requiring an integrated circuit package large enough to individually provide the physical distance requirements. Using a set of isolation barriers in series enables the use of smaller, lighter solid state isolation barriers that have smaller integrated circuit packages. The integrated circuit packages can be individually physically smaller than the physical distance requirements. Additionally, the use of smaller integrated circuit packages enables greater flexibility in circuit board design and isolation barrier placement relative to existing technologies.

### Electrical Isolation System

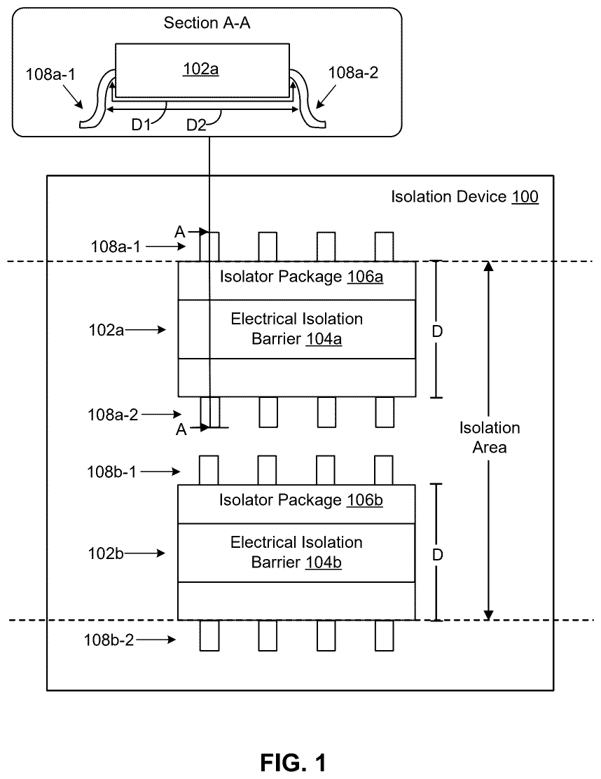

FIG. 1 is a diagram of an example of an isolation system 100, according to various embodiments. The isolation system 100 includes, without limitation, an isolator 102a and an isolator 102b (isolators 102). The isolator 102a includes, without limitation, an electrical isolation barrier 104a, an isolator package 106a, connections 108a-1, and connections 108a-2. The isolator 102b includes, without limitation, an electrical isolation barrier 104b, an isolator package 106b, connections 108b-1, and connections 108b-2.

The isolator 102a is an electrical isolating component (e.g., electrical isolator) that provides physical conductor spacing including a clearance distance and a creepage distance. Generally speaking, clearance distance and creepage distance refer to different measures of conductor spacing in a circuit and/or on a circuit board. Creepage distance refers to the distance between two conductors on the surface of the board or along the surface of an insulating material. Clearance refers to the line-of-sight (e.g., shortest straight) distance between two conductors through the air. For example, distance D1, shown in section A-A is a creepage distance between connections 108a-1 and 108-2. Distance D2, shown in section A-A is a clearance distance between connections 108a-1 and 108-2. In some embodiments, the isolator 102a provides one or more physical distance requirements such as a minimum clearance and/or minimum creepage distance between connections on opposite sides of the electrical isolation barrier 104a, and/or between connections on opposite sides of the isolator package 106a.

The electrical isolation barrier 104a is a circuit or portion of the isolator 102a provides a physical or electrical separation between two circuits on opposite sides of the electrical isolation barrier 104a while enabling data and/or power transfer. For example, the electrical isolation barrier 104a isolates one or more of the connections 108a-1 from one or more of the connections 108a-2 while enabling data and/or power transfer from one or more of the connections 108a-1 to one or more of the connections 108a-2. In one embodiment, the electrical isolation barrier 104a includes an optocoupler or an optical relay. In further embodiments, the electrical isolation barrier 104a includes one or more of a transformer, another inductive coupling device, an optical isolator, optocoupler, a fiber optic link, a capacitive coupling, and/or the like. The isolator 102a uses the electrical isolation barrier 104a to create an isolation area, zone, or region that includes a clearance and a creepage distance.

The isolator package 106a includes a protective casing or package that encloses a semiconductor or other type of integrated circuit chip of the isolator 102a, such as a circuit that provides the electrical isolation barrier 104a. The isolator package 106a also provides connections 108a-1 and 108a-2, which connect the integrated circuit chip electrical contacts to a circuit bord or other portion of the isolation system 100. The isolator package 106a shields the integrated circuit chip from physical damage and corrosion. Different package types allow for various mounting methods, for example, on a circuit board of the isolation system 100. The mounting methods include through-hole mounting, surface mounting, and/or the like. In the embodiment shown, the isolator package 106a is a dual in-line package type. Alternatively, the isolator package 106a conforms to a package type such as a small outline integrated circuit package type, a quad flat package type, a ball grid array package type, and/or the like.

The isolator 102a and/or the isolator package 106a provide one or more physical distance requirements such as a minimum clearance and/or a minimum creepage distance between the connections 108a-1 and the connections 108a-2. For example, the isolator 102a and/or the isolator package 106a provides a minimum distance D between the connections 108a-1 and the connections 108a-2. In some embodiments, the distance D is less than a physical spacing requirement of a safety standard such as UL2735. However, in some embodiments, two times D is greater than or equal to the physical spacing requirement of a safety standard such as UL2735.

The isolator 102b is an electrical isolating component (e.g., electrical isolator) that provides physical conductor spacing including a clearance distance and a creepage distance. In some embodiments, the isolator 102b provides one or more physical distance requirements such as a minimum clearance and/or minimum creepage distance between connections on opposite sides of the electrical isolation barrier 104b, and/or between connections on opposite sides of the isolator package 106b. The distance D can be representative of a clearance distance, a creepage distance, or another measure of physical spacing.

The electrical isolation barrier 104b is a circuit or portion of the isolator 102b provides a physical or electrical separation between two circuits on opposite sides of the electrical isolation barrier 104b while enabling data and/or power transfer. For example, the electrical isolation barrier 104b isolates one or more of the connections 108b-1 from one or more of the connections 108b-2 while enabling data and/or power transfer from one or more of the connections 108b-1 to one or more of the connections 108b-2. In one embodiment, the electrical isolation barrier 104b includes an optocoupler or an optical relay. In further, the electrical isolation barrier 104b includes one or more of a transformer, another inductive coupling device, an optical isolator, optocoupler, a fiber optic link, a capacitive coupling, and/or the like. The isolator 102b uses the electrical isolation barrier 104b to create an isolation area, zone, or region that includes a clearance and a creepage distance.

The isolator package 106b includes a protective casing or package that encloses a semiconductor or other type of integrated circuit chip of the isolator 102b, such as a circuit that provides the electrical isolation barrier 104b. The isolator package 106b also provides connections 108b-1 and 108b-2, which connect the integrated circuit chip electrical contacts to a circuit bord or other portion of the isolation system 100. The isolator package 106b shields the integrated circuit chip from physical damage and corrosion. Different package types allow for various mounting methods, for example, on a circuit board of the isolation system 100. The mounting methods include through-hole mounting, surface mounting, and/or the like. In the embodiment shown, the isolator package 106b is a dual in-line package type. Alternatively, the isolator package 106a conforms to a package type such as a small outline integrated circuit package type, a quad flat package type, a ball grid array package type, and/or the like.

The isolator 102b and/or the isolator package 106b provide one or more physical distance requirements such as a minimum clearance and/or a minimum creepage distance between the connections 108b-1 and the connections 108b-2. For example, the isolator 102b and/or the isolator package 106b provides a minimum distance D between the connections 108b-1 and the connections 108b-2. In some embodiments, the distance D is less than a physical spacing requirement of a safety standard such as UL2735. However, in some embodiments, two times D is greater than or equal to the physical spacing requirement of a safety standard such as UL2735.

The isolation system 100 provides an isolation area corresponding to an area or zone of electrical isolation. The isolation area includes a physical spacing of at least two times D between connections on one side of the isolation area and connections on another side of the isolation area. In this example, the isolation system 100 uses the isolator 102a and the isolator 102b to provide at least a distance of two times D between the connections 108a-1 of the isolator 102a and the connections 108b-2 of the isolator 102b. In some examples, the isolator 102a and the isolator 102b, power supply circuitry, and connection circuitry are disposed on a circuit board, thereby providing an isolation device.

The isolation system 100 provides the electrical isolation barrier 104a using the isolator 102a. The isolator 102a includes a first minimum distance (distance D as shown) that separates connections 108a-1 from connections 108a-2, which are on opposite sides of the electrical isolation barrier 104a. The isolation system 100 also provides the electrical isolation barrier 104b using the isolator 102b. The isolator 102b includes a second minimum distance (distance D as shown) that separates connections 108b-1 from connections 108b-2, which are on opposite sides of the electrical isolation barrier 104b. As a result, the isolation system 100 creates or provides an isolation area, zone, or region using the electrical isolation barrier 104a and the electrical isolation barrier 104b, which provides a total physical distance (distance of at least two times D as shown), which is greater than or equal to a physical spacing safety standard. This total physical distance is provided by a combination of at least the first minimum distance and the second minimum distance. The total physical distance corresponds to a clearance distance and/or a creepage distance. In some embodiments, one side of the isolation area connects to a high voltage portion of a meter device, and a second side of the isolation area connects to accessible circuitry of the meter device. In various examples, high voltage refers to a voltage greater than or equal to 480V, a voltage greater than or equal to 1000V, or a voltage greater than or equal to a threshold value. In some examples, the high voltage portion of the meter device includes load circuitry or line circuitry of the meter device.

The isolation system 100 is utilized to isolate input/output connections for meters and other devices. In some embodiments, the isolation system 100 isolates KY and/or KYZ input/output connections and corresponding data for a meter device or another type of device. In some embodiments, the isolation system 100 isolates other forms of input/output connections and corresponding data including but not limited to serial and parallel data as well as corresponding connection circuitry. Serial data and interfaces include Universal Asynchronous Receiver Transmitter (UART), two-or three-wire interface, Electronic Industries Alliance (EIA)/Telecommunications Industry Association (TIA)-232, -422, -485, and/or the like.

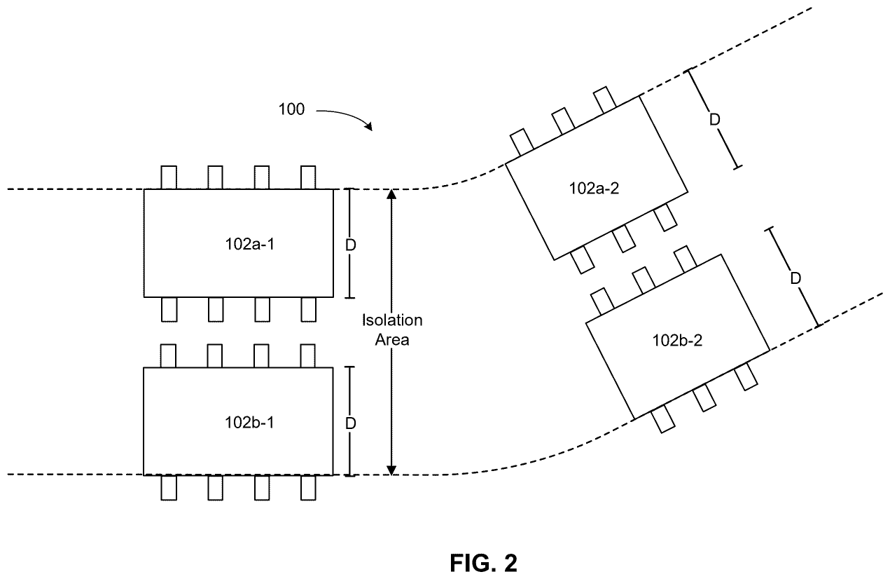

FIG. 2 is a diagram of another example of an isolation system 100, according to various embodiments. In this example, the isolation system 100 includes, without limitation, isolator 102a-1 and isolator 102a-2 (isolators 102a), as well as isolator 102b-1, and isolator 102b-2 (isolators 102b). The example of FIG. 2 shows an isolation system 100 that provides an isolation area using a set of isolators 102a and a corresponding set of isolators 102b.

While the components of the isolators 102a and 102b are unlabeled for the purpose of clarity, each of the isolators 102a and 102b include, without limitation, an electrical isolation barrier 104, an isolator package 106, and connections 108 as described with respect to the isolators 102 of FIG. 1. In the example shown, the isolators 102a-1 and 102a-2 are different, and the isolator 102a-1 is different from the isolator 102a-2. Likewise, the isolators 102b-1 and 102b-2 are different, such that the isolator 102b-1 is different from the isolator 102b-2 For instance, each of the isolator 102a-1 and the isolator 102b-1 has four connections 108 on each side, while each of the isolator 102a-2 and the isolator 102b-2 has 3 connections 108 on each side. The isolator 102a-1 can be a different type of isolator from the isolator 102a-2. The isolator 102b-1 can also be a different type of isolator from the isolator 102b-2. The isolators 102a and 102b can include any number of connections 108 on each side.

The isolation system 100 uses the two different isolators 102a to form a first side or border of the isolation area. The isolation system 100 can use any number of isolators 102a to form the first side or border of the isolation area to conform to any desired shape, such as the dotted line shown in conjunction with the isolators 102a. The isolation system 100 uses the two different isolators 102b to form a second side or border of the isolation area. The isolation system 100 can use any number of isolators 102b to form the second side or border of the isolation area to conform to any desired shape, such as the dotted line shown in conjunction with the isolators 102b. The isolation system 100 provides the isolation area corresponding to an area or region between the dotted lines.

Each of the isolators 102a and 102b is an electrical isolating component that provides physical conductor spacing including a clearance distance and a creepage distance. In some embodiments, each of the isolators 102a and 102b provides one or more physical distance requirements such as a minimum clearance and/or minimum creepage distance between connections on opposite sides of the corresponding electrical isolation barrier 104 and/or isolator package 106. For example, each isolator 102a and each isolator 102b provides a minimum distance D between the connections 108 on each side. In some embodiments, the distance D is less than a physical spacing requirement of a safety standard such as UL2735. However, in some embodiments, two times D is greater than or equal to the physical spacing requirement of a safety standard such as UL2735.

The isolation system 100 uses the set of isolators 102a and the set of isolators 102b to provide an isolation area that includes a physical spacing of at least two times D between connections on one side of the isolation area and connections on another side of the isolation area. The isolation system 100 provides electrical isolation barriers 104 using the set of isolators 102a. The isolation system 100 also provides electrical isolation barriers 104 using the set of isolators 102b. As a result, the isolation system 100 provides an isolation area using the electrical isolation barriers 104 corresponding to each of the isolators 102 of the set of isolators 102a and the set of isolators 102b. In some embodiments, the isolation system 100 connects each isolator 102a in series with a corresponding isolator 102b. In some embodiments, one side of the isolation area connects to a high voltage portion of a meter device, and a second side of the isolation area connects to accessible circuitry of the meter device.

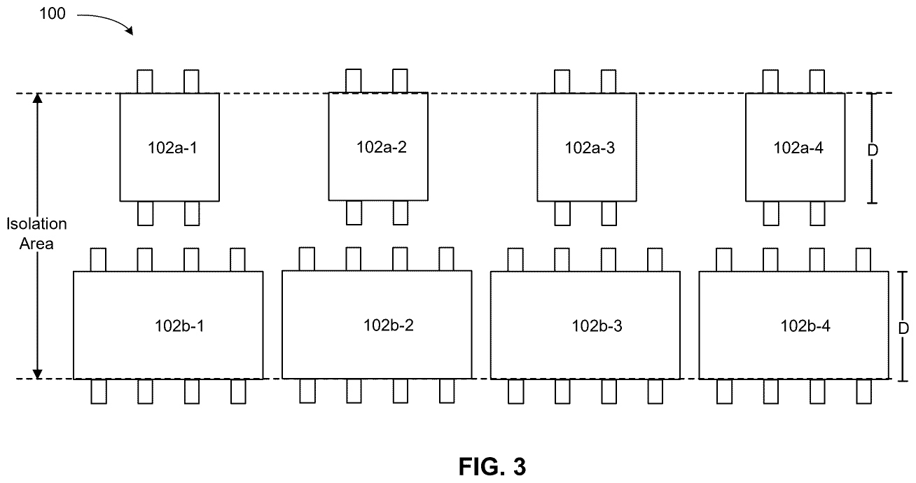

FIG. 3 is a diagram of another example of an isolation system 100, according to various embodiments. In this example, the isolation system 100 includes, without limitation, isolator 102a-1, isolator 102a-2, isolator 102a-3, and isolator 102a-4 (isolators 102a), as well as isolator 102b-1, isolator 102b-2, isolator 102b-3, and isolator 102b-4 (isolators 102b). The example of FIG. 3 shows an isolation system 100 that provides an isolation area using a set of isolators 102a that is different from the set of isolators 102b.

While the components of each of the isolators 102a are unlabeled for the purpose of clarity, each of the isolators 102a and 102b include, without limitation, an electrical isolation barrier 104, an isolator package 106, and connections 108 as described with respect to the isolators 102 of FIG. 1. While each of the isolators 102a are shown to have the same number of connections 108, each of the isolators 102a can include any number of connections 108 on each side. The isolation system 100 uses four isolators 102a to form a first side or border of the isolation area. The isolation system 100 can use any number of isolators 102a to form the first side or border of the isolation area to conform to any desired shape, for example, as shown by the dotted line in conjunction with the isolators 102a. While each of the isolators 102b are shown to have the same number of connections 108, each of the isolators 102b can include any number of connections 108 on each side. The isolation system 100 uses four isolators 102b to form a second side or border of the isolation area. The isolation system 100 can use any number of isolators 102b to form the second side or border of the isolation area to conform to any desired shape, for example, as shown by the dotted line in conjunction with the isolators 102b. The isolators 102a can be a different type of isolator than the isolators 102b. In one example, the isolators 102a are optocouplers while the isolators 102b are optical relays.

Each of the isolators 102a and 102b is an electrical isolating component that provides physical conductor spacing including a clearance distance and a creepage distance. In some embodiments, each of the isolators 102a provides one or more physical distance requirements such as a minimum clearance and/or minimum creepage distance between connections on opposite sides of the corresponding electrical isolation barrier 104 and/or isolator package 106. For example, each isolator 102a and 102b provides a minimum distance D between the connections 108 on each side. In some embodiments, the distance D is less than a physical spacing requirement of a safety standard such as UL2735. However, in some embodiments, two times D is greater than or equal to the physical spacing requirement of a safety standard such as UL2735.

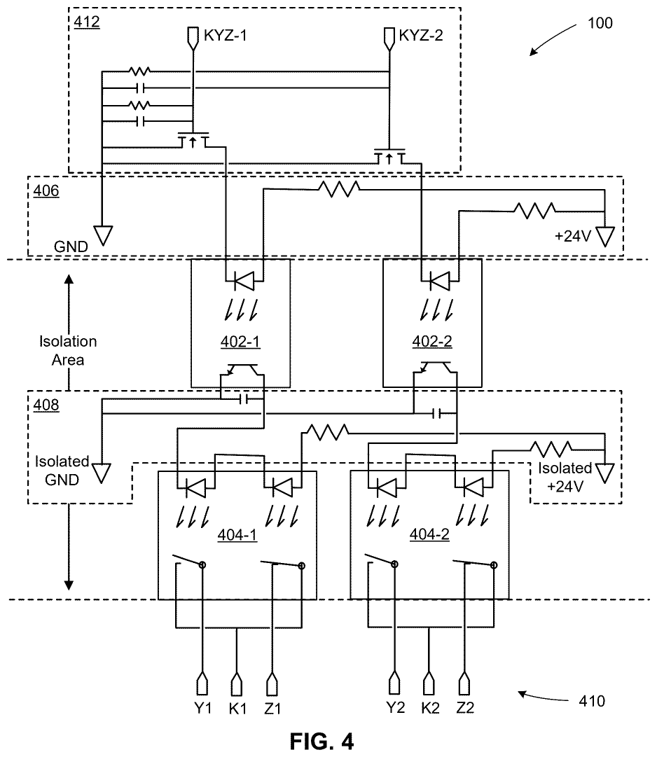

FIG. 4 is an electrical schematic diagram of the isolation system 100, according to various embodiments. As shown in FIG. 4, the isolation system 100 includes, without limitation, optocouplers 402-1 and 402-2 (optocouplers 402), optical relays 404-1 and 404-2 (optical relays 404), power supply circuit 406 and power supply circuit 408 (power supply circuits 406), accessible connection circuitry 410, and load (and/or line) connection circuitry 412.

Each of the optocouplers 402 is a type of isolator 102 that provides an electrical isolation barrier 104, for example, using a light emitting diode and a bipolar junction transistor as shown. Light from the light emitting diode activates the bipolar junction transistor to enable current flow. The activation of the bipolar junction transistor using the light emitting diode provides a physical or electrical separation between two circuits on opposite sides of the optocoupler 402, while enabling data to be transferred across the barrier (e.g., optically) and power to flow (and/or cease to flow) from the power supply circuit 406-2 to one or more of the optical relays 404.

Each of the optocouplers 402 is an electrical isolating component that provides physical conductor spacing including a clearance distance and a creepage distance. In some embodiments, each of the optocouplers 402 is a solid-state device that provides one or more physical distance requirements such as a minimum clearance and/or minimum creepage distance between connections on opposite sides of the corresponding electrical isolation barrier 104 and/or isolator package 106 of the optocoupler 402. In some embodiments, the physical spacing provided by an optical relay 404 is less than a physical spacing requirement of a safety standard such as UL2735. However, in some embodiments, two times the physical spacing provided by an optocoupler 402 is greater than or equal to the physical spacing requirement of a safety standard such as UL2735.

Each of the optical relays 404 is a type of isolator 102 that provides an electrical isolation barrier 104, for example, using one or more (e.g., two) light emitting diodes that optically communicate across the electrical isolation barrier 104 to a normally open contact and a normally closed contact as shown. The normally open contact and the normally closed contact can include a circuit that includes a bipolar junction transistor. Light from the light emitting diode activates a bipolar junction transistor to affect a corresponding contact. The activation of a bipolar junction transistors using a corresponding light emitting diode provides a physical or electrical separation between two circuits on opposite sides of the optical relay 404, while enabling data to be transferred across the barrier (e.g., optically) by opening and/or closing the contacts of the optical relay 404, which are connected to the accessible connection circuitry 410.

Each of the optical relays 404 is an electrical isolating component that provides physical conductor spacing including a clearance distance and a creepage distance. In some embodiments, each of the optical relays 404 is a solid-state device that provides one or more physical distance requirements such as a minimum clearance and/or minimum creepage distance between connections on opposite sides of the corresponding electrical isolation barrier 104 and/or isolator package 106 of the optical relay 404. In some embodiments, the physical spacing provided by an optical relay 404 is less than a physical spacing requirement of a safety standard such as UL2735. However, in some embodiments, two times the physical spacing provided by an optical relay 404 is greater than or equal to the physical spacing requirement of a safety standard such as UL2735.

The power supply circuit 406 provides power for the optocouplers 402-1 and 402-2. For example, the power supply circuit 406 provides 24V or another voltage lower than a voltage of “KYZ-1” and “KYZ-2” of the load (and/or line) connection circuitry 412. In the example shown, the power supply circuit 406 includes a voltage (or other power) source and a ground. The voltage and/or current of the power supply circuit 406 is selected based on power specifications of the optocouplers 402-1 and 402-2 (e.g., the LEDs therein). In the example shown, the power supply circuit 406 includes a resistor connected in series with the diode of the optocoupler 402-1 and a field-effect transistor (FET) of the load connection circuitry 412, between the voltage source and ground. The power supply circuit 406 includes a resistor connected in series with the diode of the optocoupler 402-2 and a FET of the load connection circuitry 412, between the voltage source and ground. The respective resistances of the resistors of the power supply circuit 406 are selected to provide a current that activates the LEDs of the optocouplers 402-1 and 402-2. While shown outside of the isolation area, in some examples the components of the power supply circuit 406 are provided within the isolation area.

The power supply circuit 408 provides power for the optical relays 404-1 and 404-2. For example, the power supply circuit 408 provides 24V or another voltage lower than a voltage of “KYZ-1” and “KYZ-2” of the load (and/or line) connection circuitry 412. In the example shown, the power supply circuit 408 includes a voltage (or other power) source and a ground. The voltage and/or current of the power supply circuit 408 is selected based on power specifications of the optical relays 404-1 and 404-2 (e.g., the LEDs therein). In the example shown, the power supply circuit 408 includes a resistor connected in series with the diode of the optical relay 404-1, between the voltage source and ground. The power supply circuit 408 includes a resistor connected in series with the diode of the optical relay 404-2, between the voltage source and ground. The respective resistances of the resistors of the power supply circuit 408 are selected to provide a current that activates the LEDs of the optical relays 404-1 and 404-2. The power supply circuit 408 includes a capacitor connected between the emitter and collector of the bipolar junction transistor of optical relay 404-1. The emitter of the bipolar junction transistor of optical relay 404-1 is connected to ground. The power supply circuit 408 includes a capacitor connected between the emitter and collector of the bipolar junction transistor of optical relay 404-2. The emitter of the bipolar junction transistor of optical relay 404-2 is connected to ground. While shown within the isolation area, in some examples the components of the power supply circuit 408 are provided outside of the isolation area.

Accessible connection circuitry 410 includes wiring and/or circuitry that connects to and/or includes accessible parts or circuitry, for example, of a meter device. Accessible circuitry includes cables exiting a meter protective cover such that it is accessible to a user or person. For example, Accessible connection circuitry 410 includes one or more electrical connectors (e.g., Type 1 connectors, J-connectors, and/or another type of connectors) corresponding to Y1, K1, Z1, Y2, K2, and Z2. Accessible connection circuitry 410 includes a first set of one or more accessible KYZ connections K1, Y1, and Z1. Accessible connection circuitry 410 includes a second set of one or more accessible KYZ connections K2, Y2, and Z2. K1 and K2 are “common” connections, Y1 and Y1 are “normally open” connections, and Z1 and Z2 are “normally closed” connections.

In some embodiments, the load (and/or line) connection circuitry 412 includes wiring and/or circuitry that connects to and/or includes a high voltage circuitry, for example, of a meter device. The load connection circuitry 412 includes one or more electrical connections to circuitry that provides KYZ pulse data. For example, KYZ-1 and KYZ-2 correspond to connections to circuits that provide KYZ pulse data. In some examples, the KYZ pulse data is provided using high voltage, corresponding to a high voltage portion of a meter device. In the example shown, the load connection circuitry 412 includes connection KYZ-1 and connection KYZ-2. Connection KYZ-1 is connected to a gate of a FET such as a metal oxide semiconductor FET (MOSFET) or another transistor. A resistor and a capacitor connect in parallel from connection KYZ-1 to ground. Connection KYZ-2 is connected to a gate of a FET such as a MOSFET or another transistor. A resistor and a capacitor connect in parallel from connection KYZ-2 to ground.

The isolation system 100 uses the set of optocouplers 402 and the set of optical relays 404 to provide an isolation area that includes a standards-compliant physical spacing between connections on one side of the isolation area and connections on another side of the isolation area. As a result, the isolation system 100 provides an isolation area using the electrical isolation barriers corresponding to each of the set of optocouplers 402 and the set of optical relays 404. In this example, each optocoupler 402 is substantially connected in series with a corresponding optical relay 404 to provide the standards-compliant physical spacing between connections on one side of the isolation area. In other embodiments, other combinations of series-connected isolators 102 can provide the isolation area. For example, two optocouplers 402 can be connected in series to provide the isolation area, two optical relays 404 can be connected in series to provide the isolation area, two fiber optic link devices can be connected in series to provide the isolation area, a6nd/or the like. Any combination of two isolators 102 or any type can be connected in series to provide the isolation area. In some examples, the optocouplers 402, optical relays 404, power supply circuits 406 and 408 are disposed on a circuit board and are provided as an isolation device for use with an electrical system that includes accessible circuitry, load (and/or line) circuitry, and/or other circuitry. In some examples, the circuit board and/or isolation device also includes accessible connection circuitry 410 and/or load connection circuitry 412.

In one example of operation, the isolation system 100 receives KYZ pulse data from KYZ pulse circuitry connected to connection KYZ-1. The KYZ pulse data activates a FET or other component of the load (and/or line) connection circuitry 412. Activation of the gate of the FET connected to KYZ-1 causes power from the power supply circuit 406 to activate the light emitting diode of optocoupler 402-1. Activating the light emitting diode of optocoupler 402-1 causes light emitted by the light emitting diode to activate the bipolar junction transistor of optocoupler 402-1. Activating the bipolar junction transistor of optocoupler 402-1 causes power from the power supply circuit 408 to activate the light emitting diodes corresponding to the normally open contact of optical diode 404-1 and the normally closed contact of optical diode 404-1. Activating the light emitting diodes causes the normally open contact of optical diode 404-1 to change states (e.g., close) and the normally closed contact of optical diode 404-1 to change states (e.g., open), thereby changing the relay state and providing the KYZ pulse data to the first set of one or more accessible KYZ connections K1, Y1, and Z1.

KYZ pulse circuitry, connected to connection KYZ-2 provides KYZ pulse data that activates a field-effect transistor (FET) or other component of the load (and/or line) connection circuitry 412. Activation of the gate of the FET connected to KYZ-2 causes power from the power supply circuit 406 to activate the light emitting diode of optocoupler 402-2. Activating the light emitting diode of optocoupler 402-1 causes light emitted by the light emitting diode to activate the bipolar junction transistor of optocoupler 402-2. Activating the bipolar junction transistor of optocoupler 402-2 causes power from the power supply circuit 408 to activate the light emitting diodes corresponding to the normally open contact of optical diode 404-2 and the normally closed contact of optical diode 404-2. Activating the light emitting diodes causes the normally open contact of optical diode 404-2 to change states (e.g., close) and the normally closed contact of optical diode 404-2 to change states (e.g., open), thereby changing the relay state and providing the KYZ pulse data to the first set of one or more accessible KYZ connections K1, Y1, and Z1.

While the isolation system 100 shown isolates KY and/or KYZ outputs from load-side and/or line-side connections into a meter, the isolation system 100 can isolate other forms of input/output signals or communication, including but not limited to serial and parallel data as well as corresponding connection circuitry. Serial data and interfaces include UART, two-or three-wire interface, EIA/TIA-232,-422,-485, and/or the like.

### Providing Electrical Isolation

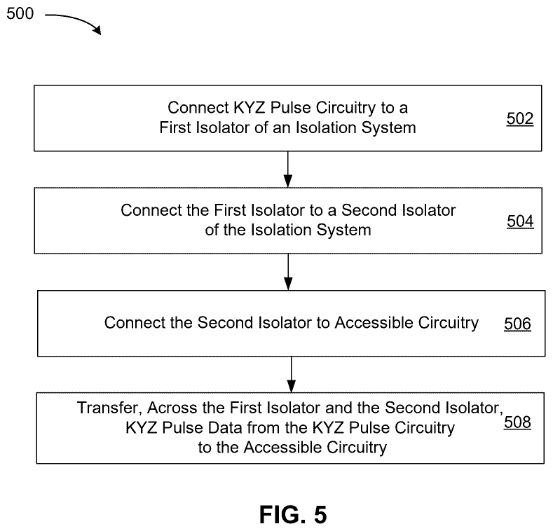

FIG. 5 illustrates a flow diagram of method steps for providing electrical isolation using an isolation system 100, according to various embodiments. Although the method steps are described in conjunction with the systems of FIGS. 1-4, persons of ordinary skill in the art will understand that any system configured to perform the method steps, in any order, is within the scope of the invention.

As shown, a method 500 begins at step 502, where KYZ pulse circuitry is connected to the first isolator 102a of an isolation system 100. The first isolator 102a creates a first region of electrical isolation using the first electrical isolation barrier 104. The first isolator 102a (and the first electrical isolation barrier 104) includes a first minimum distance or physical spacing that separates connections of the first isolator 102a that are on opposite sides of the first electrical isolation barrier 104. The first minimum distance or physical spacing is less than the physical spacing safety standard threshold distance.

At step 504, the first isolator 102a of the isolation system 100 is connected to a second isolator 102b of the isolation system 100. The second isolator 102b creates a second region of electrical isolation using second electrical isolation barrier 104. The second isolator 102b (and the second electrical isolation barrier 104) includes a second minimum distance or physical spacing that separates connections of the second isolator 102b that are on opposite sides of the second electrical isolation barrier 104. The second minimum distance or physical spacing is less than the physical spacing safety standard threshold distance.

At step 506, the second isolator 102b of the isolation system 100 is connected to accessible connection circuitry 410. As a result, an isolation area or combined region of electrical isolation provided between the accessible connection circuitry 410 and the KYZ pulse circuitry provides a total physical distance greater than or equal to a physical spacing safety standard threshold distance. The total physical distance is provided using a combination of the first minimum distance and the second minimum distance.

At step 508, the first isolator 102a of the isolation system 100 transfers, using the first isolator 102a and the second isolator 102b, KYZ pulse data from the KYZ pulse circuitry to the accessible connection circuitry 410. For example, the isolation system 100 receives KYZ pulse data from KYZ pulse circuitry. In some embodiments, load connection circuitry 412 and a power supply circuit 406 provide the KYZ pulse data to the first isolator 102a, such as an optocoupler 402. The first isolator 102a transfers the KYZ pulse data across the first electrical isolation barrier 104. In some embodiments, a power supply circuit 408 transfers the KYZ pulse data to the second isolator 102b. The second isolator 102b transfers the KYZ pulse data across the second electrical isolation barrier 104 and to the accessible connection circuitry 410.

In sum, techniques are disclosed herein for double electrical isolation systems, such as those usable to isolate accessible circuitry (e.g., KYZ meter outputs) from high-voltage circuitry. According to various embodiments, a first isolator provides a first electrical isolation barrier, where the first isolator comprises a first minimum distance that separates connections of the first isolator that are on opposite sides of the first electrical isolation barrier. A second isolator that provides a second electrical isolation barrier, wherein the second isolator comprises a second minimum distance that separates connections of the second isolator that are on opposite sides of the second electrical isolation barrier. An isolation area provided using the first electrical isolation barrier and the second electrical isolation barrier provides a physical distance greater than or equal to a physical spacing safety standard. The physical distance is provided by a combination of the first minimum distance and the second minimum distance.

At least one technical advantage of the disclosed techniques is that the disclosed techniques provide one or more physical distance requirements without requiring an integrated circuit package large enough to individually provide the physical distance requirements. Using a set of isolation barriers connected or coupled in series enables the use of smaller, lighter solid state isolation barriers that have smaller integrated circuit packages. The integrated circuit packages can be individually physically smaller than the physical distance requirements. Additionally, the use of smaller integrated circuit packages enables greater flexibility in circuit board design and isolation barrier placement relative to existing technologies.

1. In some embodiments, an isolation device comprises a first isolator that provides a first electrical isolation barrier, wherein the first isolator comprises a first minimum distance that separates connections of the first isolator that are on opposite sides of the first electrical isolation barrier, and a second isolator that provides a second electrical isolation barrier, wherein the second isolator comprises a second minimum distance that separates connections of the second isolator that are on opposite sides of the second electrical isolation barrier, wherein an isolation area provided using the first electrical isolation barrier and the second electrical isolation barrier provides a physical distance greater than or equal to a physical spacing threshold, and the physical distance is provided by a combination of the first minimum distance and the second minimum distance.

2. The isolation device of clause 1, wherein at least one of the first isolator or the second isolator is a solid state optocoupler.

3. The isolation device of clauses 1 or 2, wherein at least one of the first isolator or the second isolator is a solid-state optical relay.

4. The isolation device of any of clauses 1-3, wherein a first side of the isolation area connects to a high voltage portion of a meter device, and a second side of the isolation area connects to accessible circuitry of the meter device.

5. The isolation device of any of clauses 1-4, wherein the high voltage portion corresponds to load circuitry or line circuitry of the meter device.

6. The isolation device of any of clauses 1-5, wherein the first electrical isolation barrier provides a boundary between a high voltage portion of a meter device, and the second electrical isolation barrier.

7. The isolation device of any of clauses 1-6, wherein the second electrical isolation barrier provides a boundary between the first electrical isolation barrier, and accessible circuitry of a meter device.

8. The isolation device of any of clauses 1-7, further comprising a power supply circuit that provides power for at least one of the first isolator or the second isolator.

9. The isolation device of any of clauses 1-8, wherein electrical components of the power supply circuit are outside of the isolation area.

10. The isolation device of any of clauses 1-9, wherein the physical spacing threshold is defined in a physical spacing safety standard and both of the first minimum distance and the second minimum distance are less than the physical spacing safety standard.

11. In some embodiments, an electrical system comprises high voltage circuitry, accessible circuitry, and an isolation device comprising a first electrical isolating component coupled to a second electrical isolating component to provide a distance between a first side of an area of electrical isolation of the isolation device, and a second side of the area of electrical isolation, wherein the distance includes a combination of a first distance of the first electrical isolating component and a second distance of the second electrical isolating component, and the distance is greater than or equal to a physical spacing threshold.

12. The electrical system of clause 11, wherein at least one of the first electrical isolating component or the second electrical isolating component is an optocoupler.

13. The electrical system of clauses 11 or 12, wherein at least one of the first isolating component or the second isolating component is an optical relay.

14. The electrical system of any of clauses 11-13, wherein a first side of the area of electrical isolation connects to the high voltage circuitry, and a second side of the area of electrical isolation connects to the accessible circuitry.

15. The electrical system of any of clauses 11-14, wherein the high voltage circuitry includes load circuitry or line circuitry of a meter device.

16. The electrical system of any of clauses 11-15, wherein the first electrical isolating component comprises a first electrical isolation barrier that provides the first distance between the high voltage circuitry and the second electrical isolating component.

17. The electrical system of any of clauses 11-16, wherein the second electrical isolating component comprises a second electrical isolation barrier that provides the second distance between the first electrical isolating component and the accessible circuitry.

18. The electrical system of any of clauses 11-17, wherein the isolation device further comprises at least one power supply circuit that provides power for at least one of the first electrical isolating component or the second electrical isolating component.

19. The electrical system of any of clauses 11-18, wherein the area of electrical isolation provides an isolation voltage, and the isolation voltage is provided based on a first isolation voltage of the first electrical isolating component and a second isolation voltage of the second electrical isolating component.

20. In some embodiments, a method comprises creating a first region of electrical isolation using a first isolator, wherein the first region includes a first distance between a first side of the first isolator and a second side of the first isolator, and creating a second region of electrical isolation using a second isolator, wherein the second region includes a second distance between a first side of the second isolator and a second side of the second isolator, and connecting the first isolator to the second isolator to provide a combined region of electrical isolation that combines the first region of electrical isolation and the second region of electrical isolation, wherein the combined region of electrical isolation provides a total distance greater than or equal to a physical spacing threshold, and the total distance includes a combination of the first distance and the second distance.

Any and all combinations of any of the claim elements recited in any of the claims and/or any elements described in this application, in any fashion, fall within the contemplated scope of the present protection.

The descriptions of the various embodiments have been presented for purposes of illustration but are not intended to be exhaustive or limited to the embodiments disclosed. Many modifications and variations will be apparent to those of ordinary skill in the art without departing from the scope and spirit of the described embodiments.

Aspects of the present embodiments can be embodied as a system, method or computer program product. Accordingly, aspects of the present disclosure can take the form of an entirely hardware embodiment, an entirely software embodiment (including firmware, resident software, micro-code, etc.) or an embodiment combining software and hardware aspects that can all generally be referred to herein as a “module,” a “system,” or a “computer.” In addition, any hardware and/or software technique, process, function, component, engine, module, or system described in the present disclosure can be implemented as a circuit or set of circuits. Furthermore, aspects of the present disclosure can take the form of a computer program product embodied in one or more computer readable media having computer readable program code embodied thereon.

Any combination of one or more computer readable media can be utilized. The computer readable medium can be a computer readable signal medium or a computer readable storage medium. A computer readable storage medium can be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium can be any tangible medium that can contain or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions can be provided to a processor of a general-purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors can be, without limitation, general purpose processors, special-purpose processors, application-specific processors, or field-programmable gate arrays.

Flowcharts and block diagrams in the figures illustrate the architecture, functionality, and operation of possible implementations of systems, methods and computer program products according to various embodiments of the present disclosure. In this regard, each block in the flowchart or block diagrams can represent a module, segment, or portion of code, which comprises one or more executable instructions for implementing the specified logical function(s). It should also be noted that, in some alternative implementations, the functions noted in the block can occur out of the order noted in the figures. For example, two blocks shown in succession can, in fact, be executed substantially concurrently, or the blocks can sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure can be devised without departing from the basic scope thereof, and the scope thereof is determined by the claims that follow. Moreover, in the above description, numerous specific details are set forth to provide a more thorough understanding of the various embodiments. However, it will be apparent to one skilled in the art that the inventive concepts may be practiced without one or more of these specific details.

What is claimed is:

1. An isolation device, comprising:
a first isolator that provides a first electrical isolation barrier, wherein the first isolator comprises a first minimum distance that separates connections of the first isolator that are on opposite sides of the first electrical isolation barrier; and
a second isolator that provides a second electrical isolation barrier, wherein the second isolator comprises a second minimum distance that separates connections of the second isolator that are on opposite sides of the second electrical isolation barrier;
wherein: an isolation area provided using the first electrical isolation barrier and the second electrical isolation barrier provides a physical distance greater than or equal to a physical spacing threshold; and
the physical distance is provided by a combination of the first minimum distance and the second minimum distance.

2. The isolation device of claim 1, wherein at least one of the first isolator or the second isolator is a solid state optocoupler.

3. The isolation device of claim 1, wherein at least one of the first isolator or the second isolator is a solid-state optical relay.

4. The isolation device of claim 1, wherein a first side of the isolation area connects to a high voltage portion of a meter device, and a second side of the isolation area connects to accessible circuitry of the meter device.

5. The isolation device of claim 4, wherein the high voltage portion corresponds to load circuitry or line circuitry of the meter device.

6. The isolation device of claim 1, wherein the first electrical isolation barrier provides a boundary between a high voltage portion of a meter device, and the second electrical isolation barrier.

7. The isolation device of claim 1, wherein the second electrical isolation barrier provides a boundary between the first electrical isolation barrier, and accessible circuitry of a meter device.

8. The isolation device of claim 1, further comprising:
a power supply circuit that provides power for at least one of the first isolator or the second isolator.

9. The isolation device of claim 8, wherein electrical components of the power supply circuit are outside of the isolation area.

10. The isolation device of claim 1, wherein the physical spacing threshold is defined in a physical spacing safety standard and both of the first minimum distance and the second minimum distance are less than the physical spacing safety standard.

11. An electrical system, comprising:
high voltage circuitry;
accessible circuitry; and
an isolation device comprising a first electrical isolating component coupled to a second electrical isolating component to provide a distance between a first side of an area of electrical isolation of the isolation device, and a second side of the area of electrical isolation,
wherein the distance includes a combination of a first distance of the first electrical isolating component and a second distance of the second electrical isolating component, and the distance is greater than or equal to a physical spacing threshold.

12. The electrical system of claim 11, wherein at least one of the first electrical isolating component or the second electrical isolating component is an optocoupler.

13. The electrical system of claim 11, wherein at least one of the first isolating component or the second isolating component is an optical relay.

14. The electrical system of claim 11, wherein a first side of the area of electrical isolation connects to the high voltage circuitry, and a second side of the area of electrical isolation connects to the accessible circuitry.

15. The electrical system of claim 11, wherein the high voltage circuitry includes load circuitry or line circuitry of a meter device.

16. The electrical system of claim 11, wherein the first electrical isolating component comprises a first electrical isolation barrier that provides the first distance between the high voltage circuitry and the second electrical isolating component.

17. The electrical system of claim 11, wherein the second electrical isolating component comprises a second electrical isolation barrier that provides the second distance between the first electrical isolating component and the accessible circuitry.

18. The electrical system of claim 11, wherein the isolation device further comprises:
at least one power supply circuit that provides power for at least one of the first electrical isolating component or the second electrical isolating component.

19. The electrical system of claim 11, wherein the area of electrical isolation provides an isolation voltage, and the isolation voltage is provided based on a first isolation voltage of the first electrical isolating component and a second isolation voltage of the second electrical isolating component.

20. A method, comprising:
creating a first region of electrical isolation using a first isolator, wherein the first region includes a first distance between a first side of the first isolator and a second side of the first isolator; and
creating a second region of electrical isolation using a second isolator, wherein the second region includes a second distance between a first side of the second isolator and a second side of the second isolator; and
connecting the first isolator to the second isolator to provide a combined region of electrical isolation that combines the first region of electrical isolation and the second region of electrical isolation, wherein the combined region of electrical isolation provides a total distance greater than or equal to a physical spacing threshold, and the total distance includes a combination of the first distance and the second distance.
